(19) United States
(12) Patent Application Publication
(10) Pub. No.: US 2026/0024494 A1
(43) Pub. Date: Jan. 22, 2026

(54) DISPLAY PANEL AND DISPLAY DEVICE INCLUDING THE SAME

(71) Applicant: LG Display Co., Ltd., Seoul (KR)

(72) Inventors: Guen Sik LEE, Paju-si (KR); Seung Tae JIN, Paju-si (KR); Dong Kyu LEE, Paju-si (KR)

(73) Assignee: LG Display Co., Ltd., Seoul (KR)

(21) Appl. No.: 19/217,615

(22) Filed: May 23, 2025

(30) Foreign Application Priority Data
Jul. 18, 2024 (KR) 10-2024-0095174

(51) Int. Cl. G09G 3/3233; G09G 3/20; H10H 29/855; H10K 59/80

(52) U.S. Cl. CPC G09G 3/3233; G09G 3/2074; H10H 29/855; H10K 59/879; G09G 2300/0819; G09G 2300/0852; G09G 2300/0861; G09G 2310/08; G09G 2320/068; G09G 2358/00

(57) ABSTRACT

The present disclosure relates to a display panel and a display device including the same. The sub-pixel arranged in the display panel includes a first light-emitting element; a second light-emitting element; a first driver connected to a first data line to which a first data voltage is applied and gate lines to which gate signals are applied; a second driver connected to a second data line to which a second data voltage is applied and the gate lines to which the gate signals are applied; a mode selector connected to the first driver, the second driver, the first light-emitting element, the second light-emitting element, and mode selection lines to which mode selection signals are applied.

### CROSS-REFERENCE TO RELATED APPLICATION

This application claims priority to and the benefit of Korean Patent Application No. 10-2024-0095174, filed Jul. 18, 2024, the disclosure of which is incorporated herein by reference in its entirety.

### BACKGROUND

### Technical Field

The present disclosure relates to a display panel with variable viewing angle and a display device including the same.

### Description of Related Art

A viewing angle variable technology is being applied to display devices. The variable viewing angle technology allows video content or visual information reproduced on a display device to be visible only to a user within a narrow viewing angle range, or to multiple users within a wide viewing angle range.

As the market for future vehicles such as electric vehicles and autonomous vehicles expands, the demand for in-vehicle display devices is growing rapidly. Research is being conducted on how to split the screen of an in-vehicle display device so that one portion of the screen is controlled at a narrow viewing angle and another portion is controlled at a wide viewing angle. This technology can display private content or information that only a specific user can see on pixels driven at the narrow viewing angle, while displaying shared content that multiple users can view together on the pixels driven at the wide viewing angle.

### BRIEF SUMMARY

The present disclosure is directed to a pixel technology that can freely control each pixel at a narrow viewing angle or a wide viewing angle.

The present disclosure provides a display device capable of separating pixel data of personal content and pixel data of shared content in each of the pixels and enhancing privacy protection function.

The features of the present disclosure are not limited to those mentioned herein, and other features not mentioned may be clearly understood by those skilled in the art from the description herein.

A display panel according to an embodiment includes: a plurality of data lines, a plurality of gate lines, a plurality of power lines, a plurality of mode selection lines, and a plurality of sub-pixels. Each of the sub-pixels includes: a first light-emitting element; a second light-emitting element; a first driver connected to a first data line to which a first data voltage is applied and gate lines to which gate signals are applied; a second driver connected to a second data line to which a second data voltage is applied and the gate lines to which the gate signals are applied; and a mode selector connected to the first driver, the second driver, the first light-emitting element, the second light-emitting element, and the mode selection lines to which mode selection signals are applied.

The display panel may further include: a wide viewing angle lens overlapping with an emission area of the first light-emitting element; and a narrow viewing angle lens overlapping with an emission area of the second light-emitting element.

The first driver may include: a first driving element including a first electrode connected to a first node, a gate electrode connected to a second node, and a second electrode connected to a third node; a first capacitor connected between the second node and a fourth node; a first switching element connected between the second node and the third node; a second switching element connected between the first data line and the fourth node; a third switching element connected between the fourth node and a third power line; a fourth switching element connected between the third node and a fifth node; a fifth switching element connected between the third power line and the fifth node; and a sixth switching element connected between the third power line and an anode electrode of the second light-emitting element. The first node may be connected to a first power line.

The second driver may include: a second driving element including a first electrode connected to the first node, a gate electrode connected to a sixth node, and a second electrode connected to a seventh node; a second capacitor connected between the sixth node and an eighth node; a seventh switching element connected between the sixth node and the seventh node; an eighth switching element connected between the second data line and the eighth node; a ninth switching element connected between the eighth node and the third power line; and a tenth switching element connected between the seventh node and a ninth node.

The mode selector may include: an eleventh switching element connected between the fifth node and the ninth node; a twelfth switching clement connected between the fifth node and an anode electrode of the first light-emitting element; and a thirteenth switching element connected between the ninth node and an anode electrode of the second light-emitting element. Cathode electrodes of the first and second light-emitting elements may be connected to a second power line.

A display device according to an embodiment includes: a display panel comprising a plurality of data lines, a plurality of gate lines, a plurality of power lines, a plurality of mode selection lines, and a plurality of sub-pixels; a data driver configured to output a first data voltage and a second data voltage; and a gate driver configured to output a first scan signal, a second scan signal, a first emission signal, and a second emission signal. Each of the sub-pixels includes: a first light-emitting element; a second light-emitting element; a first driver connected to a first data line to which the first data voltage is applied and gate lines to which the first scan signal, the second scan signal, the first emission signal, and the second emission signal are applied; a second driver connected to a second data line to which the second data voltage is applied and gate lines to which the first scan signal, the second scan signal, the first emission signal, and the second emission signal are applied; and a mode selector connected to the first driver, the second driver, the first light-emitting element, the second light-emitting element, and the mode selection lines to which mode selection signals are applied.

The first driver may include: a first driving element comprising a first electrode connected to a first node to which a pixel driving voltage is applied, a gate electrode connected to a second node, and a second electrode connected to a third node; a first capacitor connected between the second node and a fourth node; a first switching clement connected between the second node and the third node, which turns on in response to a gate-on voltage of the first scan signal; a second switching element connected between the first data line and the fourth node, which turns on in response to a gate-on voltage of the second scan signal; a third switching element connected between the fourth node and a third power line to which a reference voltage is applied, which turns on in response to a gate-on voltage of the first emission signal; a fourth switching element connected between the third node and a fifth node, which turns on in response to a gate-on voltage of the first emission signal; a fifth switching element connected between the third power line and the fifth node, which turns on in response to a gate-on voltage of the first scan signal; and a sixth switching element connected between the third power line and an anode electrode of the second light-emitting element, which turns on in response to a gate-on voltage of the first scan signal.

The second driver may include: a second driving element including a first electrode connected to the first node, a gate electrode connected to a sixth node, and a second electrode connected to a seventh node; a second capacitor connected between the sixth node and an eighth node; a seventh switching element connected between the sixth node and the seventh node, which turns on in response to a gate-on voltage of the first scan signal; an eighth switching element connected between the second data line and the eighth node, which turns on in response to a gate-on voltage of the second scan signal; a ninth switching element connected between the eighth node and the third power line, which turns on in response to a gate-on voltage of the second emission signal; and a tenth switching element connected between the seventh node and a ninth node, which turns on in response to a gate-on voltage of the second emission signal.

The mode selection signals may include a first mode selection signal, a second mode selection signal, and a third mode selection signal. The mode selector may include: an eleventh switching element connected between the fifth node and the ninth node, which turns on in response to a gate-on voltage of the first mode selection signal; a twelfth switching element connected between the fifth node and an anode electrode of the first light-emitting element, which turns on in response to a gate-on voltage of the second mode selection signal; and a thirteenth switching element connected between the ninth node and an anode electrode of the second light-emitting element, which turns on in response to a gate-on voltage of the third mode selection signal. Cathode electrodes of the first and second light-emitting elements may be connected to a second power line to which a cathode voltage is applied. Each of the driving elements and the switching elements may include a transistor that turns on in response to the gate-on voltage and turns off in response to a gate-off voltage.

A voltage of the first scan signal may be the gate-on voltage during an initialization period and a sampling period set after the initialization period, and may be the gate-off voltage during an emission period set after the sampling period. A voltage of the second scan signal may be the gate-on voltage during the sampling period, and may be the gate-off voltage during the initialization period and the emission period.

A voltage of the first emission signal may be the gate-on voltage during the initialization period and the emission period, and may be the gate-off voltage during the sampling period. A voltage of the second emission signal may be the gate-on voltage during the initialization period, and may be the gate-off voltage during the sampling period and the emission period.

Voltages of the first emission signal and the second emission signal may be the gate-on voltage during the initialization period and the emission period, and may be the gate-off voltage during the sampling period.

A voltage of the first emission signal may be the gate-on voltage during the initialization period, and may be the gate-off voltage during the sampling period and the emission period. A voltage of the second emission signal may be the gate-on voltage during the initialization period and the emission period, and may be the gate-off voltage during the sampling period.

Voltages of the first mode selection signal and the second mode selection signal may be the gate-on voltage during the initialization period, the sampling period, and the emission period. A voltage of the third mode selection signal may be the gate-off voltage during the initialization period, the sampling period, and the emission period.

Voltages of the second mode selection signal and the third mode selection signal may be the gate-on voltage during the initialization period, the sampling period, and the emission period. A voltage of the first mode selection signal may be the gate-off voltage during the initialization period, the sampling period, and the emission period.

Voltages of the first mode selection signal and the third mode selection signal may be the gate-on voltage during the initialization period, the sampling period, and the emission period. A voltage of the second mode selection signal may be the gate-off voltage during the initialization period, the sampling period, and the emission period.

A voltage of the third mode selection signal may be the gate-on voltage during the initialization period, the sampling period, and the emission period. Voltages of the first mode selection signal and the second mode selection signal may be the gate-off voltage during the initialization period, the sampling period, and the emission period.

The data driver may output the data voltage corresponding to pixel data and to simultaneously output a specific gray voltage set regardless of the pixel data.

The data driver may output the data voltage corresponding to pixel data, and at the same time, some output terminals of the data driver may be electrically separated from the data lines.

The present disclosure is capable of adjusting the viewing angle of pixels according to the user usage environment and the need for privacy protection of personal content. Therefore, the present disclosure provides a display device that not only enables low power consumption and process optimization, but also enables separation of pixel data of personal content and pixel data of shared content in each pixel and enhances privacy protection function.

The present disclosure is capable of protecting personal privacy by reproducing the image of privacy-protected content with a narrow viewing angle without disturbing the viewing of shared content video.

The present disclosure may prevent the phenomenon where some pixels appear black, i.e., dark, when wide viewing angle images and narrow viewing angle images are displayed together on pixels, because the present disclosure may reproduce shared content video with a wide viewing angle and simultaneously reproduce personal content video with a narrow viewing angle in a single pixel.

The effects of the present disclosure are not limited to the effects mentioned above, and other effects not mentioned may be clearly understood by those skilled in the art.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1A and FIG. 1B are block diagrams showing a display device according to an embodiment of the present disclosure;

FIG. 2 is a circuit diagram showing a pixel circuit according to an embodiment of the present disclosure;

FIG. 3 is a diagram showing an example of lenses arranged in each of the sub-pixels;

FIG. 4 is a circuit diagram showing in detail an example of the pixel circuit shown in FIG. 2;

FIG. 5 is a waveform diagram showing an example of gate signals;

FIG. 6A and FIG. 6B are diagrams showing the operation of the pixel circuit during the initialization period;

FIG. 7A and FIG. 7B are diagrams showing the operation of the pixel circuit during the sampling period;

FIG. 8A and FIG. 8B are diagrams showing the operation of the pixel circuit during the emission period of the first viewing angle mode;

FIG. 9 is a diagram showing images obtained by photographing the display panel screen viewed from the front and side of the display panel in the first viewing angle mode;

FIG. 10A and FIG. 10B are diagrams showing the operation of the pixel circuit during the emission period of the second viewing angle mode;

FIG. 11 is a diagram showing images obtained by photographing the display panel screen viewed from the front and side of the display panel in the second viewing angle mode;

FIG. 12A and FIG. 12B are diagrams showing the operation of the pixel circuit during the emission period of the third viewing angle mode;

FIG. 13 is a diagram showing images obtained by photographing the display panel screen viewed from the front and side of the display panel in the third viewing angle mode and the fourth viewing angle mode;

FIG. 14A and FIG. 14B are diagrams showing the operation of the pixel circuit during the emission period of the fourth viewing angle mode; and

FIG. 15 is a waveform diagram showing gate signals and mode selection signals applied to pixels in response to viewing angle modes changing on the time axis.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the present specification. Further, in describing the present disclosure, detailed descriptions of known related technologies may be omitted to avoid unnecessarily obscuring the subject matter of the present disclosure.

The terms such as “comprising,” “including,” “having,” and “containing” used herein are generally intended to allow other components to be added unless the terms are used with the term “only.” Any references to singular may include plural unless expressly stated otherwise.

Components are interpreted to include an ordinary error range even if not expressly stated.

When a positional or interconnected relationship is described between two components, such as “on top of,” “above,” “below,” “next to,” “connect or couple with,” “crossing,” “intersecting,” or the like, one or more other components may be interposed between them, unless “immediately” or “directly” is used.

When a temporal antecedent relationship is described, such as “after”, “following”, “next to”, “before”, or the like, it may not be continuous on a time base unless “immediately” or “directly” is used.

The terms “first,” “second,” and the like may be used to distinguish elements from each other, but the functions or structures of the components are not limited by ordinal numbers or component names in front of the components.

The following embodiments can be partially or entirely bonded to or combined with each other and can be linked and operated in technically various ways. The embodiments can be carried out independently of or in association with each other.

The pixel circuit and the gate drive circuit of the display device may include a plurality of transistors. The transistor may be implemented as a thin film transistor (TFT). The transistors may be implemented as an oxide thin film transistor (Oxide TFT) including an oxide semiconductor, a low temperature poly silicon TFT (LTPS TFT) including a low temperature poly silicon, and the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons may flow from a source to a drain. The n-channel transistor has a direction of a current flowing from the drain to the source. In the case of a p-channel transistor (p-channel metal-oxide semiconductor, since carriers are holes, a source voltage is higher than a drain voltage such that holes may flow from a source to a drain. In the p-channel transistor, since holes flow from the source to the drain, current flows from the source to the drain. It should be noted that a source and a drain of a transistor are not fixed. For example, a source and a drain may be changed according to an applied voltage. Therefore, the disclosure is not limited to a source and a drain of a transistor. In the following description, a source and a drain of a transistor will be referred to as a first electrode and a second electrode.

A gate signal swings between a gate-on voltage and a gate-off voltage. A transistor is turned on in response to a gate-on voltage and is turned off in response to a gate-off voltage. In the case of an n-channel transistor, the gate-on voltage may be a gate high voltage VGH, and the gate-off voltage may be a gate low voltage VGL. In the case of a p-channel transistor, the gate-on voltage may be the gate low voltage VGL, and the gate-off voltage may be the gate high voltage VGH.

Hereinafter, various embodiments of the present disclosure will be described in detail with reference to the accompanying drawings.

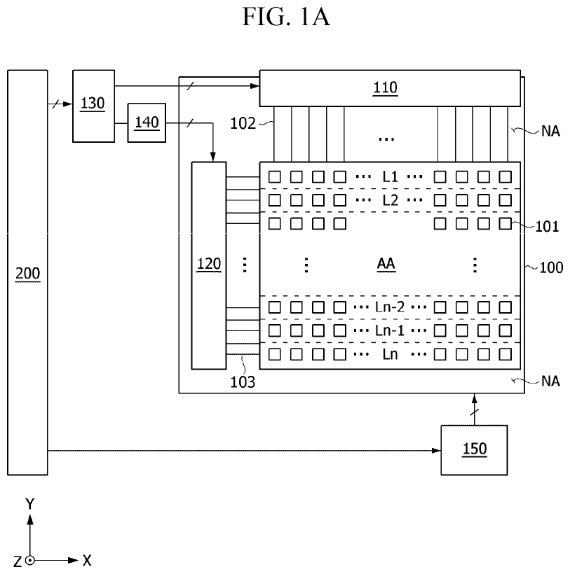

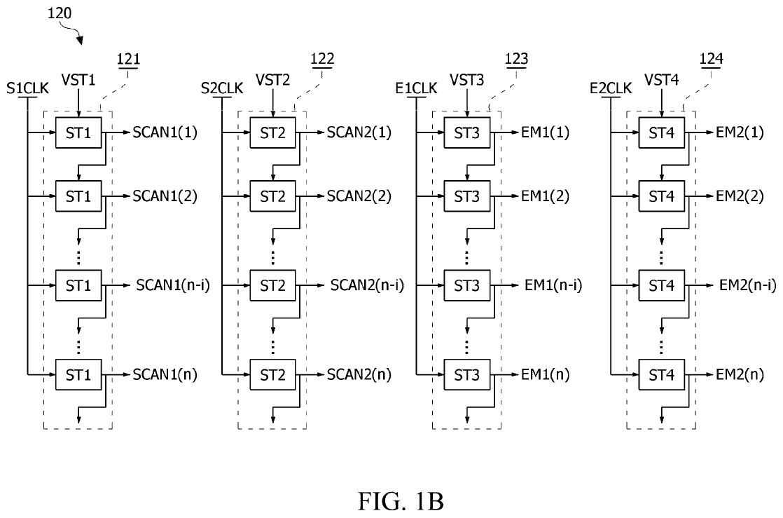

Referring to FIGS. 1A and 1B, a display device according to an embodiment of the present disclosure includes a display panel 100 and a display panel driving circuit for writing pixel data to pixels of the display panel 100. In addition, the display device includes a power supply 150.

The display panel 100 may be, but is not limited to, a panel having a rectangular structure with a length in the X-axis direction, a width in the Y-axis direction, and a thickness in the Z-axis direction. For example, the display panel 100 may be a deformed panel that is at least partially curved or elliptical.

A display area AA of the display panel 100 includes a pixel array for displaying an input image thereon. The pixel array includes a plurality of data lines 102, a plurality of gate lines 103 intersected with the data lines 102, and the pixels arranged in a matrix form. The display panel 100 may further include a plurality of power lines. The power lines are connected to constant voltage nodes of the pixel circuits and supply a constant voltage necessary for driving the pixels 101 to the pixels 101. The power lines may be implemented as striped or mesh wirings to be connected in common to the pixels 101 of the display panel 100.

Each of the pixels 101 may be divided into a red sub-pixel, a green sub-pixel, and a blue sub-pixel for color implementation. Each of the pixels may further include a white sub-pixel. Each of the sub-pixels includes a compensation part for driving a light-emitting element. Each of the pixels 101 may further include a mode control part to control a viewing angle. The light-emitting element may be a light-emitting element, such as an organic light emitting diode (OLED) or a micro light-emitting diode (LED). In the following, a pixel may be interpreted as a sub-pixel. Each of the sub-pixels may include first and second light-emitting elements that selectively emit according to the selected viewing angle mode.

The display area AA includes a plurality of pixel lines L1 to Ln. Each of the pixel lines L1 to Ln includes one line of pixels arranged along the X-axis direction in the pixel array of the display panel 100. The pixels 101 arranged in one pixel line may share the gate lines 103. The sub-pixels arranged along the Y-axis direction may share the same data line 102. One horizontal period is a time obtained by dividing one frame period by the total number of the pixel lines L1 to Ln.

The display panel 100 may be implemented as a non-transmissive display panel or a transmissive display panel. The transmissive display panel may be employed in a transparent display device in which an image is displayed on a screen and an actual object is visible beyond the display panel. The display panel 100 may be made as a flexible display panel that may be flexibly bent.

The power supply 150 receives an input voltage from a host system 200 and outputs voltages to drive the pixels 101 of the display panel 100 and the display panel driving circuit. To this end, the power supply 150 may include a direct current to direct current converter (DC-DC converter). The DC-DC converter may include a charge pump, a regulator, a buck converter, a boost converter, and the like. The power supply 150 may output constant voltages (or direct current voltages), such as the gate-on voltage, the gate-off voltage, the pixel driving voltage, the cathode voltage, the reference voltage, an IC driving voltage for the display panel driving circuit, and the like through the DC-DC converter. The gate-on voltage and the gate-off voltage may be supplied to a level shifter 140 and the gate driver 120. The voltages such as the pixel driving voltage, the cathode voltage, the reference voltage, and the like are supplied to the pixels 101 through the power lines commonly connected to the pixels 101.

The power supply 150 may further include a gamma voltage generator. The gamma voltage generator receives a high potential reference voltage and a low potential reference voltage and outputs a plurality of gamma reference voltages divided by a predetermined voltage interval on a preset gamma curve, for example, 2.2 gamma curve. The gamma reference voltages are supplied to the data driver 110. In the data driver 110, the gamma reference voltages are divided by a voltage division circuit and subdivided into grayscale voltages. The gamma voltage generator may be implemented as a programmable gamma circuit capable of adjusting each of the gamma reference voltages according to digital data. A timing controller 130 or the host system 200 or a separate external device may update digital data stored in a register of the programmable gamma circuit through a communication interface.

The display panel driving circuit writes the pixel data of the input image to the pixels 101 of the display panel 100 under the control of the timing controller 130. The display panel driving circuit includes the data driver 110 and the gate driver 120.

The display panel driving circuit may further include a touch sensor driver for driving touch sensors. The touch sensor driver is omitted from FIG. 1. The data driver 110 and the touch sensor driver may be integrated into a source drive integrated circuit (IC).

The data driver 110 receives the pixel data of the input image received as a digital signal from the timing controller 130 and outputs the data voltage. The input image may be image data including various contents such as private content, shared content, and the like. The data driver 110 may receive the gamma reference voltages and generate gamma compensated voltages for each grayscale through the voltage division circuit. A gamma-compensated voltage for each grayscale is supplied to a digital to analog converter (“DAC”) disposed on each of the channels of the data driver 110.

The data driver 110 samples and latches the digital data received from the timing controller 130, and then inputs the digital data to the DAC. Here, the digital data includes pixel data of the input image. The DAC converts the pixel data to the gamma compensated voltage and outputs the data voltage of the pixel data.

The data driver 110 may convert a non-driving voltage along with the data voltage of the pixel data. Here, the non-driving voltage may be a specific grayscale voltage set independently of the pixel data of the input image, such as a black grayscale voltage, a white grayscale voltage, or an intermediate grayscale voltage. In this case, the timing controller 130 transmits the non-driving grayscale data set to the grayscale value corresponding to the voltage level of the non-driving voltage to the data driver 110, and the data driver 110 may convert the non-driving grayscale data into a gamma compensated voltage to output the non-driving voltage.

The data driver 110 may output data voltages of pixel data under the control of the timing controller 130, and at the same time, output terminals of some channels may be electrically separated from their corresponding data line. Among the output terminals of the data driver, the output terminals that are electrically separated from the data line are in a high impedance state, and the corresponding data line is in a floating state in which no voltage is applied.

The gate driver 120 may be formed on the display panel 100 together with circuit elements of the display area AA and the wires. The gate driver 120 may be disposed in the non-display area NA on at least one of the right or left sides outside the display area AA in the display panel 100, or at least a portion thereof may be disposed within the display area AA.

The gate driver 120 may be disposed in the non-display areas NA on both sides of the display panel 100 with the display area AA of the display panel 100 interposed therebetween, and may supply gate pulses from the both sides of the gate lines 103 in a double feeding method. In another embodiment, the gate driver 120 may be disposed in at least one of the left and right non-display areas NA of the display panel 100 to supply gate signals to the gate lines 103 in a single feeding method. The gate driver 120 sequentially outputs pulses of the gate signals to the gate lines 103 under the control of the timing controller 130. The gate driver 120 may sequentially supply the gate signals to the gate lines 103 by shifting the pulses of the gate signals using a shift register or an edge trigger.

In the case that a plurality of gate signals are applied to each of the pixels, the gate driver 120 may be implemented as a plurality of gate drivers. The gate signals may include first scan signals SCAN1(1) to SCAN1(n), second scan signals SCAN2(1) to SCAN2(n), first emission signal (hereinafter referred to as an “EM signal”) EM1(1) to EM1(n), and second EM signals EM2(1) to EM2(n) input to the pixel circuit through a plurality of gate lines, as shown in FIG. 1B. In this case, the gate driver 120 may include a first gate driver 121 that outputs the first scan signals SCAN1(1) to SCAN1(n), a second gate driver 122 that outputs the second scan signal SCAN2(1) to SCAN2(n), a third gate driver 123 that outputs the first EM signals EM1(1) to EM1(n), and a fourth gate driver 124 that outputs the second EM signal EM2(1) to EM2(n).

The timing controller 130 receives from the host system 200 digital video data of the input image and a timing signal synchronized with this data. The timing signal may include a vertical synchronization signal Vsync, a horizontal synchronization signal Hsync, and a data enable signal DE. Since a vertical period and a horizontal period may be known by counting the data enable signal DE, the vertical synchronization signal Vsync and the horizontal synchronization signal Hsync may be omitted. The horizontal synchronization signal Hsync and the data enable signal DE have a period of one horizontal period (1H).

The timing controller 130 generates a data timing control signal for controlling the operation timing of the data driver 110, a gate timing control signal for controlling the operation timing of the gate driver 120, and a mode selection signal to control the viewing angle mode of each of the pixels 101, based on the timing signals Vsync, Hsync, and DE received from the host system 200, thereby controlling the pixels 101 and the display panel driving circuit. The timing controller 130 synchronizes the data driver 110 and the gate driver 120 by controlling the operation timing of the display panel driving circuit.

A gate timing control signal output from the timing controller 130 may be input to the gate driver 120 through the level shifter 140. The level shifter 140 may convert a voltage level of the gate timing signal received from the timing controller 130 to swing between the gate-on voltage and the gate-off voltage and supply it to the gate driver 120. The clock signals output from the level shifter 140 may include the start signal and the clock different for each gate driver, as shown in FIG. 1B, to independently control the rising edges, gate-on voltage periods, and falling edges of each of the gate signals SCAN1, SCAN2, EM1, and EM2.

The mode selection signal output from the timing controller 130 may be input to the level shifter 140. The level shifter 140 may convert the mode selection signal received from the timing controller 130 into a mode selection signal that swings between a gate-on voltage and a gate-off voltage. The mode select signal selects the viewing angle of the pixels and the data voltage of the pixel data written to the pixels.

The display panel driving circuit may be driven at a variable refresh rate (VRR) under the control of the timing controller 130 or the host system 200. For example, the timing controller 130 may reduce power consumption of the display device by analyzing the input image and lowering the refresh rate when the input image does not change by a preset amount of time. For example, the display panel driving circuit may lower the refresh rate of the pixels P to control a data writing period of the pixels P to be longer when a still image is input for a certain period of time or more under the control of the timing controller 130, thereby reducing the power consumption of the display device. The driving circuit of the display panel 100 may reduce the refresh rate when the display device is operated in standby mode or in response to a user command. Further, the refresh rate may be lowered in an always on display (AOD) screen. The AOD screen is a small area of pixels in the display area AA in which preset information, for example, brief information such as remaining battery power, time, and the like are displayed in the standby mode.

The host system 200 may scale an image signal from a video source to match the resolution of the display panel 100, and may transmit it to the timing controller 130 together with the timing control signal. The host system 200 may transmit a mode signal for controlling the viewing angle together with the image signal, and a flag signal indicating the presence or absence of data of personal content that requires privacy protection to the timing controller 130. The timing controller 130 controls the gate signals output from the gate driver 120 and mode selection signals in the viewing angle mode selected by the mode signal from the host system 200, and controls the data driver 110 in the selected viewing angle mode.

FIG. 1B is a diagram showing an example of the gate driver 120. In FIG. 1B, at (n-i), i is a positive integer less than n.

Referring to FIG. 1B, the first gate driver 121 includes a plurality of signal transmission parts STI connected dependently. The first gate driver 121 receives a first start signal VST1 and a first clock S1CLK to sequentially output pulses of a first scan signal SCAN1(1) to SCAN1(n). The second gate driver 122 includes a plurality of signal transmission parts ST2 connected dependently. The second gate driver 122 receives a second start signal VST2 and a second clock S2CLK to sequentially output pulses of a second scan signal SCAN2(1) to SCAN2(n).

The third gate driver 123 includes a plurality of signal transmission parts ST3 connected dependently. The third gate driver 123 receives a third start signal VST3 and a third clock E1CLK to sequentially output pulses of a first EM signal EM1(1) to EM1(n). The fourth gate driver 124 includes a plurality of signal transmission parts ST4 connected dependently. The fourth gate driver 124 receives a fourth start signal VST4 and a fourth clock E2CLK to sequentially output pulses of a second EM signal EM2(1) to EM2(n).

The clocks S1CLK to E2CLK input to the gate drivers 121-124 may include two or more clocks with different phases. The start signals VST1 to VST4 and the clocks S1CLK to E2CLK may differ from each other in at least one of phase, frequency, and duty ratio.

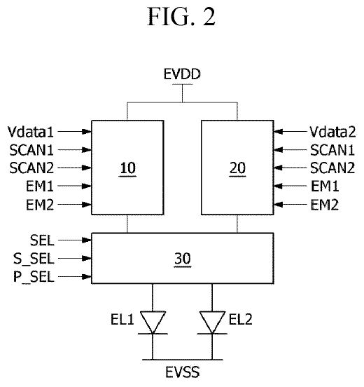

Each of the pixels 101 may include a pixel circuit as shown in FIG. 2.

FIG. 2 is a circuit diagram showing a pixel circuit according to an embodiment of the present disclosure.

Referring to FIG. 2, each of the sub-pixels of the display panel 100 includes a first light-emitting element EL1, a second light-emitting element EL2, a first driver 10, a second driver 20, and a mode selector 30.

Each of the first and second light-emitting elements EL1, EL2 may be a light-emitting element such as an OLED (Organic Light Emitting Diode) or a micro LED (Light Emitting Diode), but is not limited thereto. When the first light-emitting element EL1 emits light, light from the first light-emitting element EL may be emitted with a wide viewing angle. When the second light-emitting element EL2 emits light, light from the second light-emitting element EL2 may be emitted with a narrow viewing angle.

The first driver 10 receives a pixel driving voltage EVDD, a first data voltage Vdata1, and gate signals SCAN1, SCAN2, EM1, and EM2 to generate a current determined according to the first data voltage Vdata1 to drive at least one of the first and second light-emitting elements EL1 and EL2. The first data voltage Vdata1 may be a data voltage of pixel data of content reproduced with a wide viewing angle on the display panel 100, or a data voltage of pixel data of content reproduced with a narrow viewing angle.

The second driver 20 receives a pixel driving voltage EVDD, a second data voltage Vdata2, and gate signals SCAN1, SCAN2, EM1, and EM2 to generate a current determined according to the second data voltage Vdata2 to drive the second light-emitting element EL2. The second data voltage Vdata2 may be a data voltage of pixel data of personal content reproduced with a narrow viewing angle on the display panel 100, particularly pixel data of privacy-protected personal content. Pixel data of privacy-protected personal content may be input to the timing controller 130 with an activated level flag signal. Pixel data received with an activated level flag signal may be converted to the second data voltage Vdata2. Meanwhile, pixel data received with a deactivated level flag signal may be converted to the first data voltage Vdata1.

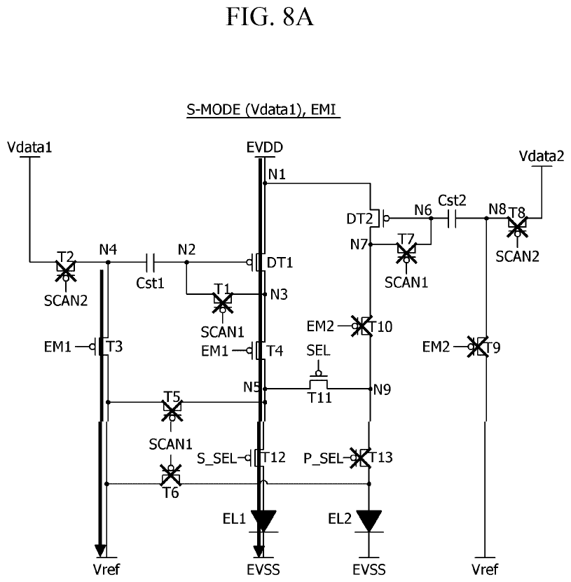

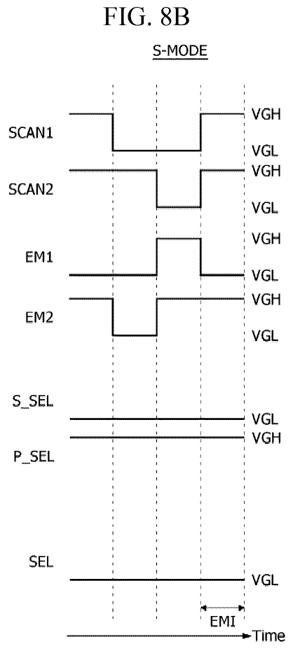

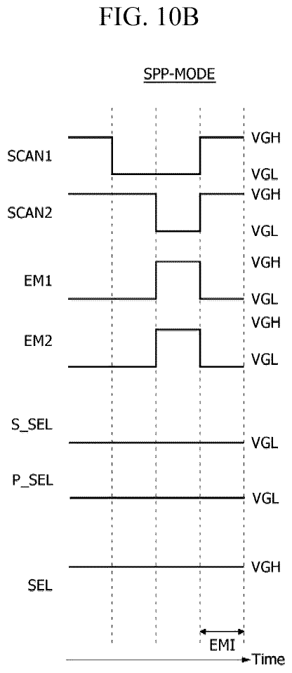

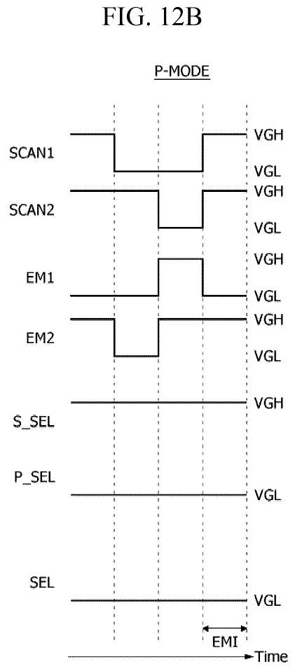

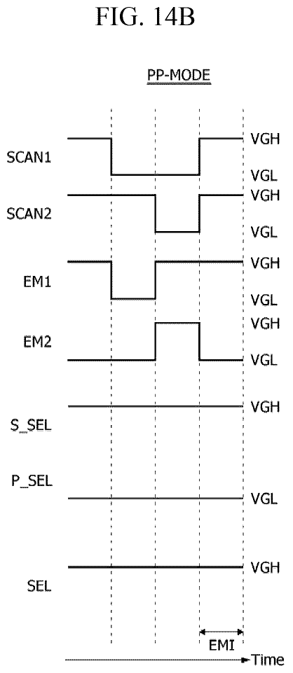

The mode selector 30 selectively supplies the current generated from the first driver 10 and the current generated from the second driver 20 to the light-emitting elements EL1 and EL2 under the control of the timing controller 130. The mode selector 30 selects a light-emitting element EL1 and EL2 to be driven in a selected viewing angle mode among a first viewing angle mode (S-MODE in FIG. 8A and FIG. 8B,), a second viewing angle mode (SPP-MODE in FIG. 10A and FIG. 10B,) a third viewing angle mode (P-MODE in FIG. 12A and FIG. 12B), and a fourth viewing angle mode (PP-MODE in FIG. 14A and FIG. 14B,). The mode selector 30 can control the first driver 10 and the second driver 20 based on the mode selection signals to drive at least one of the first light-emitting element EL1 and the second light-emitting element EL2 to emit light.

In a pixel driven in the first viewing angle mode S-MODE, the first light-emitting clement EL1 is driven by a current generated according to the first data voltage Vdata1. When the first light-emitting element EL1 emits light, light emitted from the first light-emitting element EL1 proceeds with a wide viewing angle. In the case of the display device being installed in a vehicle, the first viewing angle mode S-MODE may be selected when both the vehicle driver and passengers enjoy shared content such as movies and sports during the non-driving period of the vehicle.

In the second viewing angle mode SPP-MODE, the first light-emitting element EL1 is driven by a current generated according to the first data voltage Vdata1, and simultaneously, the second light-emitting element EL2 is driven by a current generated according to the second data voltage Vdata2. In this case, light emitted from the first light-emitting element EL1 proceeds with a wide viewing angle, and simultaneously, light emitted from the second light-emitting element EL2 proceeds with a narrow viewing angle.

In the case of the second viewing angle mode SPP-MODE, when the vehicle driver and passengers are watching shared content video, a user who exists in the narrow viewing angle can see privacy-protected content, for example, SNS or text data, without disturbing the other users's video viewing. In the pixel area driven in the second viewing angle mode S-MODE, personal content received with an activated level flag signal is visible only from the front of the display panel, and the shared content video is visible from a wide viewing angle, so privacy may be protected by limiting the viewing angle of personal content without disturbing the other users's viewing of shared content.

In the third viewing angle mode P-MODE, the second light-emitting element EL2 is driven by a current generated according to the first data voltage Vdata1. In the third viewing angle mode P-MODE, pixel data of the input image converted to the first data voltage Vdata1 may be reproduced with a narrow viewing angle. When the vehicle is driving, the third viewing angle mode P-MODE may make the pixels of the display panel 100 emit light with a narrow viewing angle so that the driver's attention is not distracted by videos that the passenger is watching. In this case, the first data voltage Vdata1 may be a data voltage of pixel data of shared content or personal content.

In the fourth viewing angle mode PP-MODE, the second light-emitting element EL2 is driven by a current generated according to the second data voltage Vdata2. In the fourth viewing angle mode, pixel data of the input image converted to the second data voltage Vdata2 may be reproduced with a narrow viewing angle.

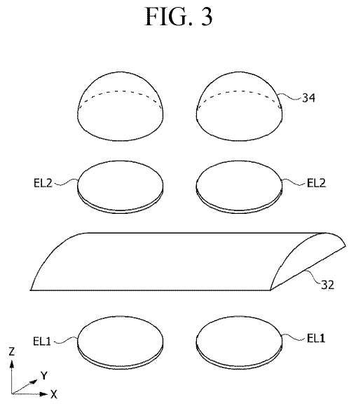

FIG. 3 is a diagram showing an example of lenses arranged on light-emitting elements.

Referring to FIG. 3, the first lens 32 is a wide viewing angle lens arranged above the first light-emitting element EL1. The first lens 32 overlaps with the emission area of the first light-emitting element EL1. The first lens 32 may be implemented as a semi-cylindrical lens to limit the up-down viewing angle and widen the left-right viewing angle. The first lens 32 is long in the left-right direction (or X-axis direction) of the display panel 100 and narrow in the up-down direction (Y-axis direction). The first lens 32 concentrates light from the first light-emitting element EL1 in the up-down direction and diffuses it with a wide viewing angle in the left-right direction, causing light from the first light-emitting element EL1 to proceed with a wide viewing angle in the left-right direction.

The second lens 34 is a narrow viewing angle lens arranged above the second light-emitting element EL2. The second lens 34 overlaps with the emission area of the second light-emitting element EL2. The second lens 34 may be a semi-spherical lens that is thick in the center and becomes thinner toward the edges in the up-down and left-right directions. The second lens 34 concentrates light from the second light-emitting element EL2 to make light emitted from the second light-emitting element EL2 proceed with a narrow viewing angle in the up-down and left-right directions.

In a case that the display device is installed in a vehicle, the first and second lenses 32, 34 may limit the up-down viewing angle of the pixel to prevent the phenomenon of pixel light being reflected and visible on the windshield of the vehicle.

The first and second lenses 32, 34 may be implemented as transparent medium or transparent insulating layer patterns arranged in the display panel 100, but are not limited thereto.

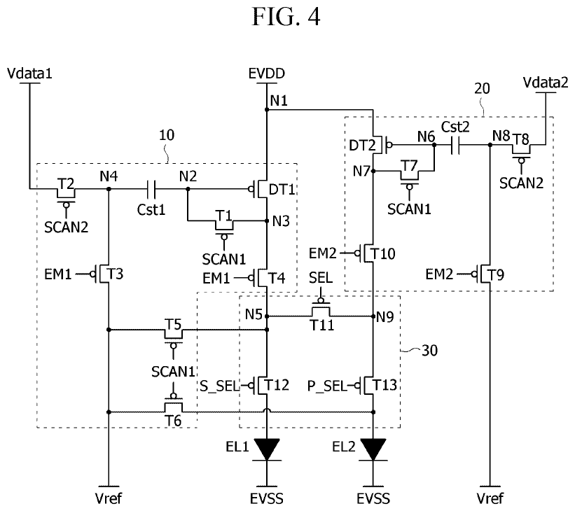

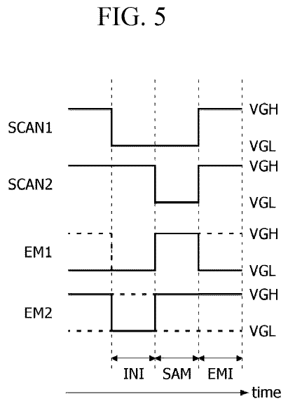

FIG. 4 is a circuit diagram showing in detail an example of the pixel circuit shown in FIG. 2. FIG. 5 is a waveform diagram showing an example of gate signals.

Referring to FIG. 4 and FIG. 5, the pixel circuit may be connected to a first power line to which a pixel driving voltage EVDD is applied, a second power line to which a cathode voltage EVSS is applied, a third power line to which a reference voltage Vref is applied, a first data line to which a first data voltage Vdata1 is applied, a second data line to which a second data voltage Vdata2 is applied, a plurality of gate lines to which gate signals SCAN1, SCAN2, EM1, and EM2 are applied, and mode selection lines to which mode selection signals SEL, S_SEL, and P_SEL are applied.

The gate signals SCAN1, SCAN2, EM1, and EM2 and the mode selection signals SEL, S_SEL, and P_SEL may swing between a gate-on voltage VGL and a gate-off voltage VGH.

The gate lines may include a first gate line to which the first scan signal SCAN1 is applied, a second gate line to which the second scan signal SCAN2 is applied, a third gate line to which the first EM signal EM1 is applied, and a fourth gate line to which the second EM signal EM2 is applied.

The mode selection lines may include a first mode selection line to which a first mode selection signal SEL is applied, a second mode selection line to which a second mode selection signal S_SEL is applied, and a third mode selection line to which a third mode selection signal P_SEL is applied.

The pixel driving voltage EVDD may be set to a voltage lower than the gate-off voltage VGH and higher than the cathode voltage EVSS. The reference voltage Vref may be the same as the cathode voltage EVSS and set to a voltage higher than the gate-on voltage VGL. The data voltages Vdata1 and Vdata2 are set with a dynamic range between a maximum voltage and a minimum voltage, and their voltage levels are selected according to the gray value of the pixel data. The maximum voltage of the data voltages Vdata1 and Vdata2 may be set to a voltage lower than the pixel driving voltage EVDD and higher than the reference voltage Vref. The minimum voltage of the data voltages Vdata1 and Vdata2 may be set to a voltage lower than the reference voltage Vref and the cathode voltage EVSS and higher than the gate-on voltage VGL. For example,

EVDD=15.0V, EVSS=Vref=3.0V, VGH=16.0V, VGL=−9.0V, and the dynamic range of the data voltages Vdata1, Vdata2 may be 0V-4.5V, but is not limited thereto. The maximum voltage of the data voltages Vdata1 and Vdata2 may be a black gray voltage or a lowest gray voltage, and the minimum voltage of the data voltages Vdata1 and Vdata2 may be a white gray voltage or a highest gray voltage.

The pixel circuit further includes a plurality of transistors DT1, DT2, and T1 to T13 and a plurality of capacitors Cst1 and Cst2. The transistors DT1, DT2, and T1 to T13 may be implemented as p-channel LTPS TFTs, but are not limited thereto.

The first driver 10 may include a first driving element DT1, first to sixth switching elements T1 to T6, and a first capacitor Cst1.

The first driving element DT1 may generate a current according to its gate-source voltage to drive one or more of the first and second light-emitting elements EL1 and EL2. The first driving element DT1 includes a first electrode connected to a first node N1, a gate electrode connected to a second node N2, and a second electrode connected to a third node N3. The first power line to which the pixel driving voltage EVDD is applied may be connected to the first node N1. The first capacitor Cst1 is connected between the second node N2 and a fourth node N4.

The first switching clement T1 is connected between the second node N2 and the third node N3. The first switching clement T1 turns on in response to the gate-on voltage VGL of the first scan signal SCAN1. When the first switching element T1 turns on, the second node N2 may be electrically connected to the third node N3. The first switching element T1 includes a gate electrode to which the first scan signal SCAN1 is applied, a first electrode connected to the second node N2, and a second electrode connected to the third node N3.

The second switching element T2 is connected between the first data line to which the first data voltage Vdata1 is applied and the fourth node N4. The second switching element T2 turns on in response to the gate-on voltage VGL of the second scan signal SCAN2. When the second switching element T2 turns on, the first data line may be electrically connected to the fourth node N4 so that the first data voltage Vdata1 may be applied to the fourth node N4. The second switching element T2 includes a gate electrode to which the second scan signal SCAN2 is applied, a first electrode to which the first data voltage Vdata1 is applied, and a second electrode connected to the fourth node N4.

The third switching element T3 is connected between the fourth node N4 and the third power line. The reference voltage Vref is applied to the third power line. The third switching element T3 turns on in response to the gate-on voltage VGL of the first EM signal EM1. When the third switching clement T3 turns on, the reference voltage Vref may be applied to the fourth node N4. The third switching element T3 includes a gate electrode to which the first EM signal EM1 is applied, a first electrode connected to the fourth node N4, and a second electrode to which the reference voltage Vref is applied.

The fourth switching element T4 is connected between the third node N3 and the fifth node N5. The fourth switching element T4 turns on in response to the gate-on voltage VGL of the first EM signal EM1 to electrically connect the third node N3 to the fifth node N5. The fourth switching element T4 includes a gate electrode to which the first EM signal EM1 is applied, a first electrode connected to the third node N3, and a second electrode connected to the fifth node N5.

The fifth switching element T5 is connected between the third power line and the fifth node N5. The fifth switching element T5 turns on in response to the gate-on voltage VGL of the first scan signal SCAN1. When the fifth switching element T5 turns on, the reference voltage Vref may be applied to the fifth node N5. The fifth switching element T5 includes a gate electrode to which the first scan signal SCAN1 is applied, a first electrode to which the reference voltage Vref is applied, and a second electrode connected to the fifth node N5.

The sixth switching element T6 is connected between the third power line and the anode electrode of the second light-emitting element EL2. The sixth switching element T6 turns on in response to the gate-on voltage VGL of the first scan signal SCAN1. When the sixth switching element T6 turns on, the reference voltage Vref may be applied to the anode electrode of the second light-emitting element EL2. The sixth switching element T6 includes a gate electrode to which the first scan signal SCAN1 is applied, a first electrode to which the reference voltage Vref is applied, and a second electrode connected to the anode electrode of the second light-emitting element EL2.

The second driver 20 may include a second driving element DT2, seventh to tenth switching elements T7-T10, and a second capacitor Cst2.

The second driving element DT2 may generate a current according to its gate-source voltage to drive the second light-emitting element EL2. The second driving element DT2 includes a first electrode connected to the first node N1, a gate electrode connected to a sixth node N6, and a second electrode connected to a seventh node N7. The second capacitor Cst2 is connected between the sixth node N6 and an eighth node N8.

The seventh switching element T7 is connected between the sixth node N6 and the seventh node N7. The seventh switching element T7 turns on in response to the gate-on voltage VGL of the first scan signal SCAN1. When the seventh switching element T7 turns on, the sixth node N6 may be electrically connected to the seventh node N7. The seventh switching element T7 includes a gate electrode to which the first scan signal SCAN1 is applied, a first electrode connected to the sixth node N6, and a second electrode connected to the seventh node N7.

The eighth switching element T8 is connected between the second data line to which the second data voltage Vdata2 is applied and the eighth node N8. The eighth switching element T8 turns on in response to the gate-on voltage VGL of the second scan signal SCAN2. When the eighth switching element T8 turns on, the second data line may be electrically connected to the eighth node N8 so that the second data voltage Vdata2 may be applied to the eighth node N8. The eighth switching element T8 includes a gate electrode to which the second scan signal SCAN2 is applied, a first electrode to which the second data voltage Vdata2 is applied, and a second electrode connected to the eighth node N8.

The ninth switching element T9 is connected between the eighth node N8 and the third power line. The ninth switching element T9 turns on in response to the gate-on voltage VGL of the second EM signal EM2. When the ninth switching element T9 turns on, the reference voltage Vref may be applied to the eighth node N8. The ninth switching element T9 includes a gate electrode to which the second EM signal EM2 is applied, a first electrode connected to the eighth node N8, and a second electrode to which the reference voltage Vref is applied.

The tenth switching element T10 is connected between the seventh node N7 and a ninth node N9. The tenth switching element T10 turns on in response to the gate-on voltage VGL of the second EM signal EM2 to electrically connect the seventh node N7 to the ninth node N9. The tenth switching element T10 includes a gate electrode to which the second EM signal EM2 is applied, a first electrode connected to the seventh node N7, and a second electrode connected to the ninth node N9.

The mode selector 30 includes eleventh to thirteenth switching elements T11, T12, T13.

The eleventh switching element T11 is connected between the fifth node N5 and the ninth node N9. The eleventh switching element T11 turns on in response to the gate-on voltage VGL of the first mode selection signal SEL to electrically connect the fifth node N5 to the ninth node N9. The eleventh switching element T11 includes a gate electrode to which the first mode selection signal SEL is applied, a first electrode connected to the fifth node N5, and a second electrode connected to the ninth node N9.

The twelfth switching clement T12 is connected between the fifth node N5 and the anode electrode of the first light-emitting element EL1. The twelfth switching element T12 turns on in response to the gate-on voltage VGL of the second mode selection signal S_SEL to electrically connect the fifth node N5 to the anode electrode of the first light-emitting element EL1. The twelfth switching element T12 includes a gate electrode to which the second mode selection signal S_SEL is applied, a first electrode connected to the fifth node N5, and a second electrode connected to the anode electrode of the first light-emitting clement EL1.

The thirteenth switching clement T13 is connected between the ninth node N9 and the anode electrode of the second light-emitting element EL2. The thirteenth switching element T13 turns on in response to the gate-on voltage VGL of the third mode selection signal P_SEL to electrically connect the ninth node N9 to the anode electrode of the second light-emitting element EL2. The thirteenth switching element T13 includes a gate electrode to which the third mode selection signal P_SEL is applied, a first electrode connected to the ninth node N9, and a second electrode connected to the anode electrode of the second light-emitting clement EL2.

The first light-emitting element EL1 includes an anode electrode connected to the second electrode of the twelfth switching element T12 and a cathode electrode connected to the second power line. The second light-emitting element EL2 includes an anode electrode connected to the second electrode of the thirteenth switching element T13 and a cathode electrode connected to the second power line. The cathode voltage EVSS is applied to the second power line.

As such, the mode selector 30 enable a selection among multiple driving paths (4 possible paths shown in FIG. 4). In the first driving path, current from the first driving element DT1 is applied to the first light-emitting element EL1 via transistors T4 and T12. In the second driving path, current from the first driving element DT1 is applied to the second light-emitting element EL2 via transistors T4, T11, and T13. In the third driving path, current from the second driving element DT2 is applied to the second light-emitting clement EL2 via transistors T10 and T13. In the fourth driving path, current from the second driving element DT2 is applied to the first light-emitting clement EL1 via transistors T10, T11, and T12.

The driving period of the pixel may be divided into an initialization period INI, a sampling period SAM, and an emission period EMI as shown in FIG. 5 to FIG. 15. During the initialization period INI, the main nodes of the pixel circuit and the capacitors Cst1 and Cst2 are initialized. During the sampling period SAM, the threshold voltages of the driving elements DT1 and DT2 are sampled and applied to one electrode of the capacitors Cst1 and Cst2, and the data voltages Vdata1 and Vdata2 are applied to the other electrode of the capacitors Cst1 and Cst2. During the emission period EMI, one or more of the light-emitting elements EL1 and EL2 may be driven and emit light by the current generated according to the gate-source voltage of the driving elements DT1 and DT2 set by the data voltages Vdata1 and Vdata2 compensated by the threshold voltage of the driving elements DT1 and DT2.

In all viewing angle modes, the scan signals SCAN1, SCAN2 are generated with the same waveform every frame period. The pulse of the first scan signal SCAN1 is generated as the gate-on voltage VGL during the initialization period INI and the sampling period SAM. The pulse width of the first scan signal SCAN1 may be approximately 2 horizontal periods. During the emission period EMI, the voltage of the first scan signal SCAN1 is the gate-off voltage VGH. The pulse of the second scan signal SCAN2 is generated as the gate-on voltage VGL during the sampling period SAM. The pulse width of the second scan signal SCAN2 may be approximately 1 horizontal period. During the initialization period INI and the emission period EMI, the voltage of the second scan signal SCAN2 is the gate-off voltage VGH.

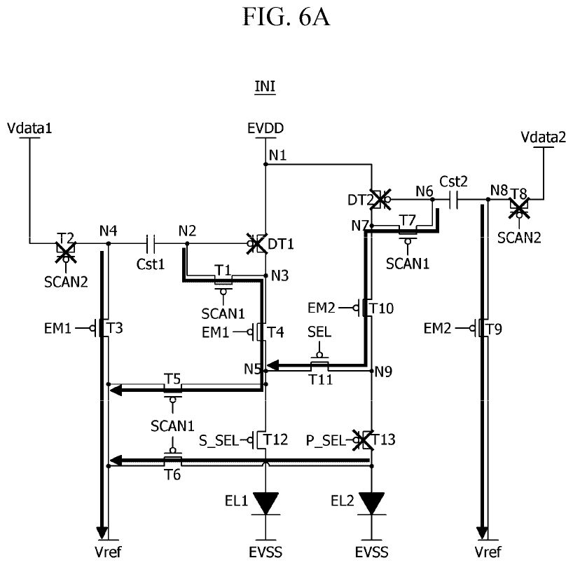

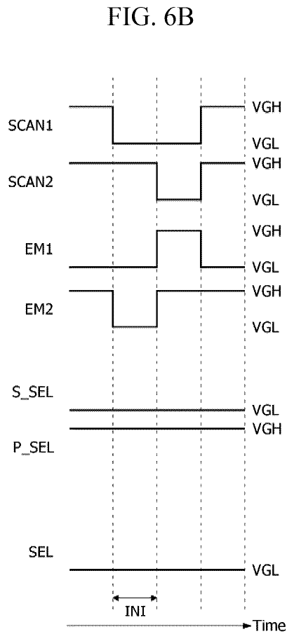

FIG. 6A and FIG. 6B are diagrams showing the operations of the pixel circuit during the initialization period.

Referring to FIG. 6A and FIG. 6B, in each of the first to fourth viewing angle modes (S-MODE, SPP-MODE, P-MODE, and PP-MODE), the pixel circuit may be initialized in the same way during the initialization period INI. During the initialization period INI, the voltages of the first scan signal SCAN1, the first EM signal EM1, and the second EM signal EM2 are the gate-on voltage VGL, and the voltage of the second scan signal SCAN2 is the gate-off voltage VGH. Therefore, during the initialization period INI, the first, third, fourth, fifth, sixth, seventh, ninth, and tenth switching elements T1, T3, T4, T5, T6, T7, T9, and T10 turn on, while the second and eighth switching elements T2 and T8 turn off.

During the initialization period INI, the voltages of the first mode selection signal SEL and the second mode selection signal S_SEL are the gate-on voltage VGL, and the voltage of the third mode selection signal P_SEL is the gate-off voltage VGH. In this case, during the initialization period INI of the first viewing angle mode S-MODE, the eleventh and twelfth switching elements T11 and T12 turn on, while the thirteenth switching element T13 turns off.

During the initialization period INI, the anode voltages of the light-emitting elements EL1 and EL2 and the voltages of the second to ninth nodes N2-N9 may be initialized to the reference voltage Vref.

The voltages of the mode selection signals SEL, S_SEL, P_SEL may be set according to the viewing angle mode. For example, in the first viewing angle mode S-MODE, the voltages of the mode selection signals SEL, S_SEL, P_SEL are as shown in FIG. 6A and FIG. 6B.

In the second viewing angle mode SPP-MODE, as shown in FIG. 10B, the voltages of the second mode selection signal S_SEL and the third mode selection signal P_SEL are the gate-on voltage VGL, and the voltage of the first mode selection signal SEL is the gate-off voltage VGH. In this case, in the second viewing angle mode SPP-MODE, the twelfth and thirteenth switching elements T12 and T13 turn on, while the eleventh switching element T11 turns off.

In the third viewing angle mode P-MODE, as shown in FIG. 12B, the voltages of the first mode selection signal SEL and the third mode selection signal P_SEL are the gate-on voltage VGL, and the voltage of the second mode selection signal S_SEL is the gate-off voltage VGH. In this case, in the third viewing angle mode P-MODE, the eleventh and thirteenth switching elements T11 and T13 turn on, while the twelfth switching element T12 turns off.

In the fourth viewing angle mode PP-MODE, as shown in FIG. 14B, the voltage of the third mode selection signal P_SEL is the gate-on voltage VGL, and the voltages of the first mode selection signal SEL and the second mode selection signal S_SEL are the gate-off voltage VGH. In this case, in the fourth viewing angle mode PP-MODE, the thirteenth switching element T13 turns on, while the eleventh and twelfth switching elements T11 and T12 turn off.

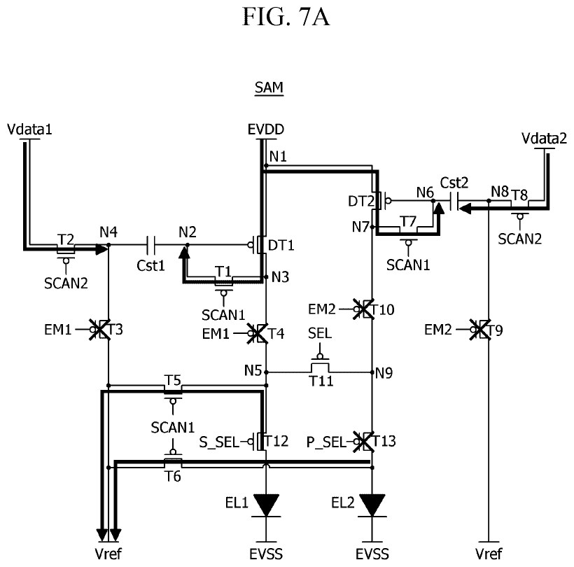

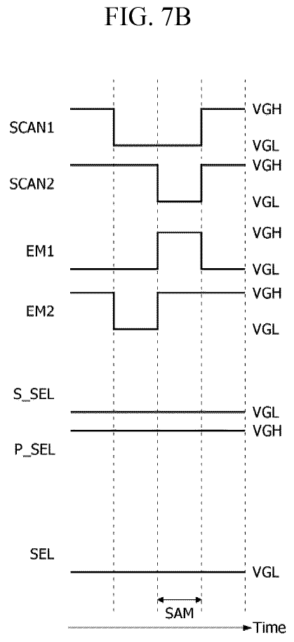

FIG. 7A and FIG. 7B are diagrams showing the operations of the pixel circuit during the sampling period.

Referring to FIG. 7A and FIG. 7B, in each of the first to fourth viewing angle modes (S-MODE, SPP-MODE, P-MODE, and PP-MODE), the pixel circuit may operate in the same way during the sampling period SAM. During the sampling period SAM, the voltages of the first scan signal SCAN1 and the second scan signal SCAN2 are the gate-on voltage VGL, and the voltages of the first EM signal EM1 and the second EM signal EM2 are the gate-off voltage VGH. Therefore, during the sampling period SAM, the first, second, fifth, sixth, seventh, and eighth switching elements T1, T2, T5, T6, T7, and T8 turn on, while the third, fourth, ninth, and tenth switching elements T3, T4, T9, and T10 turn off.

During the sampling period SAM, the voltages of the first mode selection signal SEL and the second mode selection signal S_SEL are the gate-on voltage VGL, and the voltage of the third mode selection signal P_SEL is the gate-off voltage VGH. In this case, the eleventh and twelfth switching elements T11 and T12 are in the ON state, and the thirteenth switching element T13 is in the OFF state.

During the sampling period SAM, the threshold voltage (Vth) of the first driving clement DT1 is sampled, and the first data voltage Vdata1 compensated by the threshold voltage (Vth) of the first driving clement DT1 is stored in the first capacitor Cst1. At the same time, the threshold voltage (Vth) of the second driving element DT2 is sampled, and the second data voltage Vdata2 compensated by the threshold voltage (Vth) of the second driving clement DT2 is stored in the second capacitor Cst2. At the end of the sampling period SAM, the voltage of the fourth node N4 is the first data voltage Vdata1, and the voltage of the second node N2 is EVDD+Vth. The Vth reflected on the second node N2 is the threshold voltage of the first driving clement DT1. At the end of the sampling period SAM, the voltage of the eighth node N8 is the second data voltage Vdata2, and the voltage of the sixth node N6 is EVDD+Vth. The Vth reflected on the eighth node N8 is the threshold voltage of the second driving element DT2.

The first EM signal EM1 and the second EM signal EM2 are not limited to FIG. 6B and FIG. 7B. For example, the voltages of the first EM signal EM1 and the second EM signal EM2 may be the gate-on voltage VGL during the initialization period INI and the emission period EMI, and may be the gate-off voltage VGH during the sampling period SAM, as shown in FIG. 10B.

The voltage of the first EM signal EM1 may be the gate-on voltage VGL during the initialization period INI and the gate-off voltage VGH during the sampling period SAM and the emission period EMI, as shown in FIG. 14B. The voltage of the second EM signal EM2 may be the gate-on voltage VGL during the initialization period INI and the emission period EMI, and may be the gate-off voltage VGH during the sampling period SAM, as shown in FIG. 14B.

In all viewing angle modes, the first data voltage Vdata1 and the second data voltage Vdata2 may be applied to the pixel. In this case, because the light-emitting element selected to emit light is selected according to the viewing angle mode, one of the first and second data voltages Vdata1, Vdata2 may not affect the pixel driving.

In another embodiment, one of the first and second data voltages Vdata1, Vdata2 may be a non-driving voltage or may not be applied to the data line according to the viewing angle mode. For example, during the sampling period SAM of the first viewing angle mode S-MODE, the first data voltage Vdata1 may be applied to the fourth node N4 through the first data line, and a non-driving voltage may be applied to the eighth node N8 through the second data line. In the first viewing angle mode S-MODE, the first data voltage Vdata1 output through the first channel of the data driver 110 may be output as a voltage corresponding to the gray value of the pixel data of the image input to the timing controller 130 during the non-driving period of the vehicle or the pixel data of the shared content, and its voltage may vary according to the gray value of the pixel data. In the first viewing angle mode S-MODE, a non-driving voltage may be applied to the second data line through the second channel of the data driver 110, or the second data line may be floated.

During the sampling period SAM of the second viewing angle mode SPP-MODE, the first data voltage Vdata1 may be applied to the fourth node N4 through the first data line, and the second data voltage Vdata2 may be applied to the eighth node N8 through the second data line. The first data voltage Vdata1 applied to the pixel during the sampling period SAM of the second viewing angle mode SPP-MODE may vary according to the gray value of the pixel data of the image input to the timing controller 130 during the non-driving period of the vehicle or the pixel data of the shared content, and the second data voltage Vdata2 may vary according to the gray value of the pixel data set as privacy-protected data, for example, pixel data input with an activated level flag signal.

During the sampling period SAM of the third viewing angle mode P-MODE, the first data voltage Vdata1 may be applied to the fourth node N4 through the first data line, and a non-driving voltage may be applied to the eighth node N8 through the second data line. In the third viewing angle mode P-MODE, the first data voltage Vdata1 output through the first channel of the data driver 110 may vary according to the gray value of the pixel data of the image input to the timing controller 130 during the driving period of the vehicle or the pixel data of the personal content, for example, pixel data input with a deactivated level flag signal. In the third viewing angle mode P-MODE, a non-driving voltage may be applied to the second data line through the second channel of the data driver 110, or the second data line may be floated.

During the sampling period SAM of the fourth viewing angle mode PP-MODE, the second data voltage Vdata2 may be applied to the eighth node N8 through the second data line, and a non-driving voltage may be applied to the fourth node N4 through the first data line. In the fourth viewing angle mode PP-MODE, the second data voltage Vdata2 output through the second channel of the data driver 110 may vary according to the gray value of the pixel data set as privacy-protected data, for example, pixel data input with an activated level flag signal. In the fourth viewing angle mode PP-MODE, a non-driving voltage may be applied to the first data line through the first channel of the data driver 110, or the first data line may be floated.

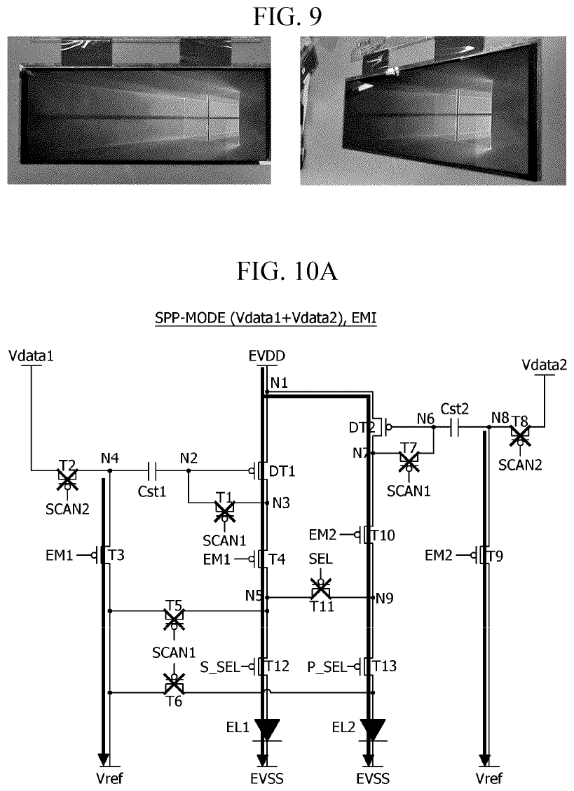

FIG. 8A and FIG. 8B are diagrams showing the operations of the pixel circuit during the emission period of the first viewing angle mode. FIG. 9 is a diagram showing images obtained by photographing the display panel screen viewed from the front and side of the display panel in the first viewing angle mode. In FIG. 9, the left diagram shows the front viewing angle image seen when looking at the screen of the display panel from the front, and the right diagram shows the side viewing angle image seen when looking at the screen of the display panel from the side.

Referring to FIG. 8A and FIG. 8B, during the emission period EMI of the first viewing angle mode S-MODE, the voltages of the first mode selection signal SEL and the second mode selection signal S_SEL are the gate-on voltage VGL, and the voltage of the third mode selection signal P_SEL is the gate-off voltage VGH. During the emission period EMI of the first viewing angle mode S-MODE, the eleventh and twelfth switching elements T11, T12 turn on, while the thirteenth switching element T13 turns off. During the emission period EMI of the first viewing angle mode S-MODE, the current generated from the first driving element DT1 may be supplied to the first light-emitting element EL1 through the fourth switching clement T4 and the twelfth switching element T12 to make the first light-emitting element EL1 emit light. At this time, because the tenth and thirteenth switching elements T10, T13 are in the off state, the second light-emitting element EL2 does not emit light. During the emission period EMI of the first viewing angle mode S-MODE, the current driving the first light-emitting element EL1 is generated according to the gate-source voltage of the first driving element DT1 generated according to the first data voltage Vdata1.

During the emission period EMI of the first viewing angle mode S-MODE, as shown in FIG. 9, the video of shared content may be visible in both the front viewing angle and the side viewing angle from the pixels driven by the first data voltage Vdata1. Therefore, pixels driven in the first viewing angle mode S-MODE may reproduce images with a wide viewing angle.

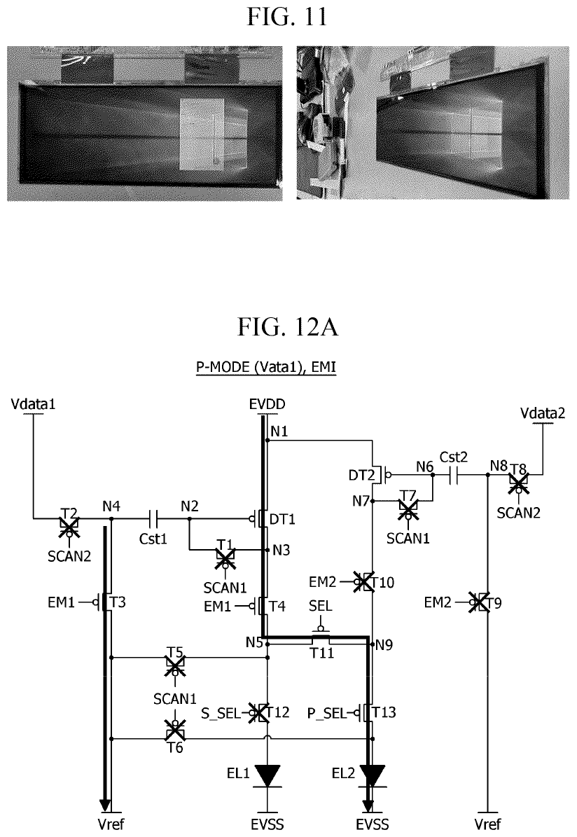

FIG. 10A and FIG. 10B are diagrams showing the operations of the pixel circuit during the emission period of the second viewing angle mode. FIG. 11 is a diagram showing images obtained by photographing the display panel screen viewed from the front and side of the display panel in the second viewing angle mode. In FIG. 11, the left diagram shows the front viewing angle image seen when looking at the screen of the display panel from the front, and the right diagram shows the side viewing angle image seen when looking at the screen of the display panel from the side.

Referring to FIG. 10A and FIG. 10B, during the emission period EMI of the second viewing angle mode SPP-MODE, the voltages of the second mode selection signal S_SEL and the third mode selection signal P_SEL are the gate-on voltage VGL, and the voltage of the first mode selection signal SEL is the gate-off voltage VGH. During the emission period EMI of the second viewing angle mode SPP-MODE, the twelfth and thirteenth switching elements T12, T13 turn on, while the eleventh switching element T11 turns off. During the emission period EMI of the second viewing angle mode SPP-MODE, the current generated from the first driving element DT1 may be supplied to the first light-emitting element EL1 through the fourth switching element T4 and the twelfth switching element T12 to make the first light-emitting element EL1 emit light, and simultaneously, the current generated from the second driving clement DT2 may be supplied to the second light-emitting element EL2 through the tenth switching element T10 and the thirteenth switching element T13 to make the second light-emitting clement EL2 emit light. During the emission period EMI of the second viewing angle mode SPP-MODE, the current driving the first light-emitting element EL1 is generated according to the gate-source voltage of the first driving element DT1 generated according to the first data voltage Vdata1, and the current driving the second light-emitting element EL2 is generated according to the gate-source voltage of the second driving element DT2 generated according to the second data voltage Vdata2.

During the emission period EMI of the second viewing angle mode SPP-MODE, as shown in FIG. 11, the front viewing angle image of shared content video may be visible together with personal content image, and in the side viewing angle, the personal content image may not be visible and only the shared content video may be visible. Therefore, pixels driven in the second viewing angle mode SPP-MODE may reproduce the video of shared content with a wide viewing angle while simultaneously reproducing the image set as privacy-protected content with a narrow viewing angle.

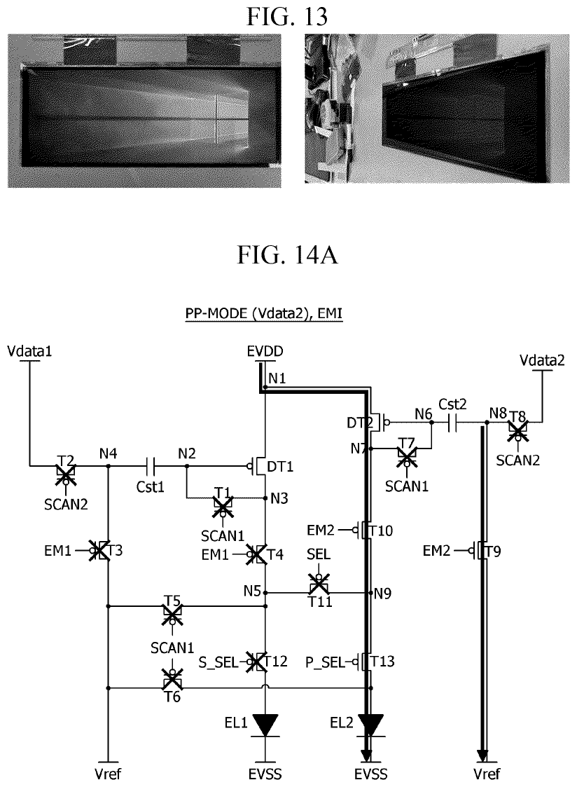

FIG. 12A and FIG. 12B are diagrams showing the operations of the pixel circuit during the emission period of the third viewing angle mode. FIG. 13 is a diagram showing images obtained by photographing the display panel screen viewed from the front and side of the display panel in the third viewing angle mode and the fourth viewing angle mode. In FIG. 13, the left diagram shows the front viewing angle image seen when looking at the screen of the display panel from the front, and the right diagram shows the side viewing angle image seen when looking at the screen of the display panel from the side.

Referring to FIG. 12A and FIG. 12B, during the emission period EMI of the third viewing angle mode P-MODE, the voltages of the first mode selection signal SEL and the third mode selection signal P_SEL are the gate-on voltage VGL, and the voltage of the second mode selection signal S_SEL is the gate-off voltage VGH. During the emission period EMI of the third viewing angle mode P-MODE, the eleventh and thirteenth switching elements T11, T13 turn on, while the twelfth switching element T12 turns off.

During the emission period EMI of the third viewing angle mode P-MODE, the current generated from the first driving element DT1 may be supplied to the second light-emitting element EL2 through the fourth switching element T4 and the thirteenth switching element T13, making the second light-emitting element EL2 emit light. At this time, because the twelfth switching element T12 is in the off state, the first light-emitting element EL1 does not emit light. During the emission period EMI of the third viewing angle mode P-MODE, the current driving the second light-emitting clement EL2 is generated according to the gate-source voltage of the first driving element DT1 generated according to the first data voltage Vdata1.

During the emission period EMI of the third viewing angle mode P-MODE, as shown in FIG. 13, the front viewing angle image is visible, and the image is not visible in the side viewing angle. Therefore, pixels driven in the third viewing angle mode P-MODE may reproduce images with a narrow viewing angle.

FIG. 14A and FIG. 14B are diagrams showing the operations of the pixel circuit during the emission period of the fourth viewing angle mode.

Referring to FIG. 14A and FIG. 14B, during the emission period EMI of the fourth viewing angle mode PP-MODE, the voltage of the third mode selection signal P_SEL is the gate-on voltage VGL, and the voltages of the first mode selection signal SEL and the second mode selection signal S_SEL are the gate-off voltage VGH. During the emission period EMI of the fourth viewing angle mode PP-MODE, the thirteenth switching element T13 turns on, while the eleventh and twelfth switching elements T11, T12 turn off.

During the emission period EMI of the fourth viewing angle mode PP-MODE, the current generated from the second driving element DT2 is supplied to the second light-emitting clement EL2 through the tenth switching element T10 and the thirteenth switching element T13 to make the second light-emitting element EL2 emit light. At this time, because the fourth and twelfth switching elements T4, T12 are in the off state, the first light-emitting element EL1 does not emit light. During the emission period EMI of the fourth viewing angle mode PP-MODE, the current driving the second light-emitting element EL2 is generated according to the gate-source voltage of the second driving element DT2 generated according to the second data voltage Vdata2.

During the emission period EMI of the fourth viewing angle mode PP-MODE, as shown in FIG. 13, the front viewing angle image is visible, and the image is not visible in the side viewing angle. When the pixel data set as privacy-protected content is converted to the second data voltage Vdata2, pixels driven in the fourth viewing angle mode PP-MODE may reproduce images that are visible only from the front viewing angle. Therefore, pixels driven in the fourth viewing angle mode PP-MODE may reproduce images with a narrow viewing angle.

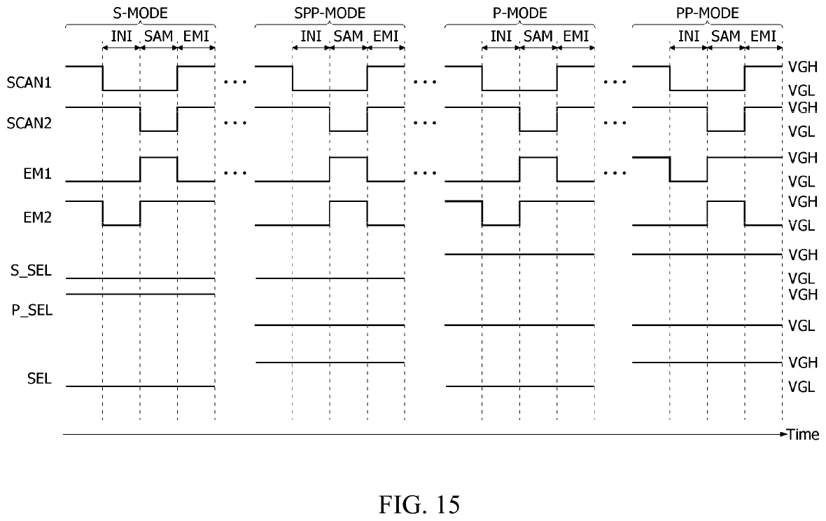

FIG. 15 is a waveform diagram showing gate signals and mode selection signals applied to pixels in response to viewing angle modes changing on the time axis. The timing controller 130 or the host system 200 may automatically change the viewing angle of the pixels on the display panel 100. Gate signals SCAN1, SCAN2, EM1, EM2 and mode selection signals SEL, S_SEL, P_SEL, which are preset for each viewing angle mode under the control of the timing controller 130, are input to each of the pixels. The viewing angle of the image reproduced in each of the pixels may be changed by the gate signals SCAN1, SCAN2, EM1, EM2 and the mode selection signals SEL, S_SEL, P_SEL.

According to one or more embodiments of the present disclosure, the display device may be applied to mobile devices, video phones, smart watches, watch phones, wearable device, foldable device, rollable device, bendable device, flexible device, curved device, sliding device, variable device, electronic organizer, electronic books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances, etc. Additionally, the display apparatus according to one or more embodiments of the present disclosure may be applied to organic light emitting lighting devices or inorganic light emitting lighting devices.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a plurality of data lines, a plurality of gate lines, a plurality of power lines, a plurality of mode selection lines, and a plurality of sub-pixels,
wherein each of the sub-pixels comprises:
a first light-emitting element;
a second light-emitting element;
a first driver connected to a first data line to which a first data voltage is configured to be applied and gate lines to which gate signals are configured to be applied;
a second driver connected to a second data line to which a second data voltage is configured to be applied and the gate lines to which the gate signals are configured to be applied; and
a mode selector connected to the first driver, the second driver, the first light-emitting element, the second light-emitting element, and the plurality of mode selection lines to which mode selection signals are configured to be applied.

2. The display panel of claim 1, further comprising:
a wide viewing angle lens overlapping with an emission area of the first light-emitting element; and
a narrow viewing angle lens overlapping with an emission area of the second light-emitting element.

3. The display panel of claim 1, wherein the first driver comprises:
a first driving element including a first electrode connected to a first node, a gate electrode connected to a second node, and a second electrode connected to a third node;
a first capacitor connected between the second node and a fourth node;
a first switching element connected between the second node and the third node;
a second switching element connected between the first data line and the fourth node;
a third switching element connected between the fourth node and a third power line;
a fourth switching element connected between the third node and a fifth node;
a fifth switching element connected between the third power line and the fifth node; and
a sixth switching element connected between the third power line and an anode electrode of the second light-emitting element,
wherein the first node is connected to a first power line.

4. The display panel of claim 3, wherein the second driver comprises:
a second driving element including a first electrode connected to the first node, a gate electrode connected to a sixth node, and a second electrode connected to a seventh node;
a second capacitor connected between the sixth node and an eighth node;
a seventh switching element connected between the sixth node and the seventh node;
an eighth switching element connected between the second data line and the eighth node;
a ninth switching element connected between the eighth node and the third power line; and
a tenth switching element connected between the seventh node and a ninth node.

5. The display panel of claim 4, wherein the mode selector comprises:
an eleventh switching element connected between the fifth node and the ninth node;
a twelfth switching element connected between the fifth node and an anode electrode of the first light-emitting element; and
a thirteenth switching element connected between the ninth node and an anode electrode of the second light-emitting element, and
wherein cathode electrodes of the first and second light-emitting elements are connected to a second power line.

6. A display device comprising:
a display panel comprising a plurality of data lines, a plurality of gate lines, a plurality of power lines, a plurality of mode selection lines, and a plurality of sub-pixels;
a data driver configured to output a first data voltage and a second data voltage; and
a gate driver configured to output a first scan signal, a second scan signal, a first emission signal, and a second emission signal,
wherein each of the sub-pixels comprises:
a first light-emitting element;
a second light-emitting element;
a first driver connected to a first data line to which the first data voltage is configured to be applied and gate lines to which the first scan signal, the second scan signal, the first emission signal, and the second emission signal are configured to be applied;
a second driver connected to a second data line to which the second data voltage is configured to be applied and gate lines to which the first scan signal, the second scan signal, the first emission signal, and the second emission signal are configured to be applied; and
a mode selector connected to the first driver, the second driver, the first light-emitting element, the second light-emitting element, and the plurality of mode selection lines to which mode selection signals are configured to be applied.

7. The display device of claim 6, wherein the first driver comprises:
a first driving element comprising a first electrode connected to a first node to which a pixel driving voltage is applied, a gate electrode connected to a second node, and a second electrode connected to a third node;
a first capacitor connected between the second node and a fourth node;
a first switching element connected between the second node and the third node, which turns on in response to a gate-on voltage of the first scan signal;
a second switching element connected between the first data line and the fourth node, which turns on in response to a gate-on voltage of the second scan signal;
a third switching element connected between the fourth node and a third power line to which a reference voltage is applied, which turns on in response to a gate-on voltage of the first emission signal;
a fourth switching element connected between the third node and a fifth node, which turns on in response to a gate-on voltage of the first emission signal;
a fifth switching element connected between the third power line and the fifth node, which turns on in response to a gate-on voltage of the first scan signal; and
a sixth switching element connected between the third power line and an anode electrode of the second light-emitting element, which turns on in response to a gate-on voltage of the first scan signal.

8. The display device of claim 7, wherein the second driver comprises:
a second driving element including a first electrode connected to the first node, a gate electrode connected to a sixth node, and a second electrode connected to a seventh node;
a second capacitor connected between the sixth node and an eighth node;
a seventh switching element connected between the sixth node and the seventh node, which turns on in response to a gate-on voltage of the first scan signal;
an eighth switching element connected between the second data line and the eighth node, which turns on in response to a gate-on voltage of the second scan signal;
a ninth switching element connected between the eighth node and the third power line, which turns on in response to a gate-on voltage of the second emission signal; and
a tenth switching element connected between the seventh node and a ninth node, which turns on in response to a gate-on voltage of the second emission signal.

9. The display device of claim 8, wherein the mode selection signals include a first mode selection signal, a second mode selection signal, and a third mode selection signal,
wherein the mode selector comprises:
an eleventh switching element connected between the fifth node and the ninth node, which turns on in response to a gate-on voltage of the first mode selection signal;
a twelfth switching element connected between the fifth node and an anode electrode of the first light-emitting element, which turns on in response to a gate-on voltage of the second mode selection signal; and
a thirteenth switching element connected between the ninth node and an anode electrode of the second light-emitting element, which turns on in response to a gate-on voltage of the third mode selection signal,
wherein cathode electrodes of the first and second light-emitting elements are connected to a second power line to which a cathode voltage is applied, and
wherein each of the driving elements and the switching elements comprises a transistor that turns on in response to the gate-on voltage and turns off in response to a gate-off voltage.

10. The display device of claim 9, wherein a voltage of the first scan signal is the gate-on voltage during an initialization period and a sampling period set after the initialization period, and is the gate-off voltage during an emission period set after the sampling period, and
a voltage of the second scan signal is the gate-on voltage during the sampling period, and is the gate-off voltage during the initialization period and the emission period.

11. The display device of claim 10, wherein a voltage of the first emission signal is the gate-on voltage during the initialization period and the emission period, and is the gate-off voltage during the sampling period, and
a voltage of the second emission signal is the gate-on voltage during the initialization period, and is the gate-off voltage during the sampling period and the emission period.

12. The display device of claim 10, wherein voltages of the first emission signal and the second emission signal are the gate-on voltage during the initialization period and the emission period, and are the gate-off voltage during the sampling period.

13. The display device of claim 10, wherein a voltage of the first emission signal is the gate-on voltage during the initialization period, and is the gate-off voltage during the sampling period and the emission period, and
a voltage of the second emission signal is the gate-on voltage during the initialization period and the emission period, and is the gate-off voltage during the sampling period.

14. The display device of claim 10, wherein voltages of the first mode selection signal and the second mode selection signal are the gate-on voltage during the initialization period, the sampling period, and the emission period, and
a voltage of the third mode selection signal is the gate-off voltage during the initialization period, the sampling period, and the emission period.

15. The display device of claim 10, wherein voltages of the second mode selection signal and the third mode selection signal are the gate-on voltage during the initialization period, the sampling period, and the emission period, and
a voltage of the first mode selection signal is the gate-off voltage during the initialization period, the sampling period, and the emission period.

16. The display device of claim 10, wherein voltages of the first mode selection signal and the third mode selection signal are the gate-on voltage during the initialization period, the sampling period, and the emission period, and
a voltage of the second mode selection signal is the gate-off voltage during the initialization period, the sampling period, and the emission period.

17. The display device of claim 10, wherein a voltage of the third mode selection signal is the gate-on voltage during the initialization period, the sampling period, and the emission period, and
voltages of the first mode selection signal and the second mode selection signal are the gate-off voltage during the initialization period, the sampling period, and the emission period.

18. The display device of claim 6, wherein the data driver is configured to output the data voltage corresponding to pixel data and to simultaneously output a specific gray voltage set regardless of the pixel data.

19. The display device of claim 6, wherein the data driver is configured to output the data voltage corresponding to pixel data, and at the same time, some output terminals of the data driver are electrically separated from the data lines.
